(19) United States
(12) Patent Application Publication
(10) Pub. No.: US 2012/0182034 A1
(43) Pub. Date: Jul. 19, 2012

(54) CONTACT ASSEMBLY

(75) Inventors: Richard J. SCHERER, Austin, TX (US); Joseph N. CASTIGLIONE, Cedar Park, TX (US); Abhay R. JOSHI, Austin, TX (US); Jesse A. MANN, Cedar Park, TX (US); James G. VANA, JR., Cedar Park, TX (US)

(73) Assignee: 3M Innovative Properties Company

(21) Appl. No.: 13/007,886

(22) Filed: Jan. 17, 2011

(51) Int. Cl. G01R 1/067; G01R 1/04

(52) U.S. Cl. 324/750.26; 324/755.05; 324/756.01

(57) ABSTRACT

A contact assembly for receiving a spring probe unit includes an elongate contact element adapted to electrically contact the spring probe unit. The contact element includes a stop for restraining movement of the spring probe unit towards the stop in the direction of an axis along the length of the contact element, and urging means, adapted to urge the spring probe unit against the contact element for removable engagement of the spring probe unit with the contact element.

### TECHNICAL FIELD

The invention relates to contact assemblies that are suitable for receiving a spring probe unit, to combinations of such contact assemblies with spring probe units and to mounting assemblies for mounting such contact assemblies.

### BACKGROUND

Automatic test equipment for semiconductor devices normally comprises a large number of electrical contact probes, each of which provides electrical contact between the test equipment and one electrical node of a semiconductor device under test. Many electrical contact probes comprise a spring-loaded tip for contacting the node, and a body, into which the tip can be depressed against the force of a spring, located in the interior of the body. An electrical contact probe of this type is often called a spring probe unit.

In most instances of semiconductor device testing, many electrical nodes need to be electrically contacted simultaneously by a number of spring probe units. For that purpose, a number of spring probe units are normally assembled in a probe block, which provides mechanical support for the bodies of those spring probe units. The probe block must provide precise positioning of the spring probe units, because the electrical nodes of the semiconductor device under test are normally very small and very close to each other.

As an example, U.S. Pat. No. 6,037,787 mentions such contact probe assemblies. In that document, a coaxial contact probe assembly includes a solid tubular shield with a coaxial signal contact probe, isolated from the shield by an insulative retainer. Upper and lower retainers are provided with the same number of holes for engaging a plurality of coaxial contact probe assemblies.

In general, the tips of a spring probe unit repeatedly establish mechanical and electrical contact with electrical nodes of the semiconductor devices under test, and wear out with use. It is therefore necessary to exchange them when one or more of them are worn out. The tip of a spring probe unit can not be removed from its body and exchanged without compromising the mechanical and electrical properties of the spring probe unit. Traditionally, it was not possible, either, to remove an entire spring probe unit from a probe block, because the spring probe unit required a tight fit with its mechanical support in the probe block for sufficiently precise positioning, and the tight fit did not allow to remove the spring probe unit without exerting excessive force, which in turn would risk to damage the probe block, adjacent spring probe units or their support. Thus, the entire probe block had often to be exchanged.

As such probe blocks are expensive, it would be desirable to provide less costly ways of replacing spring probes. In particular, it is desirable to be able to replace individual spring probe units in a probe block without compromising the mechanical and electrical properties of the test equipment as a whole. Hence, a need exists to provide a support for spring probe units which permits that an individual spring probe unit be removable from their support without the need to exert strong force. The support should further permit to engage a spring probe such that a replacement spring probe can be positioned in the support with sufficient precision and without the need to exert strong force.

### SUMMARY

The present invention addresses this problem. It provides a contact assembly for receiving a spring probe unit, which comprises an elongate contact element adapted to electrically contact the spring probe unit. The contact element comprises a stop for restraining movement of the spring probe unit towards the stop in the direction of an axis along the length of the contact element, and urging means, adapted to urge the spring probe unit against the contact element for removable engagement of the spring probe unit with the contact element.

The contact assembly according to the invention allows for precise positioning of a spring probe unit in all directions. The stop allows precise positioning in the long direction of the contact element, and the urging means allows precise positioning in the directions perpendicular to the long direction of the contact element. Due to the removable engagement of the spring probe unit with the contact element, the spring probe unit can be removed from the contact assembly by pulling the spring probe unit, in the long direction of the contact element, away from the stop, without needing to exert strong force. A replacement spring probe unit can be inserted into the contact assembly in the long direction of the contact element into abutment with the stop, such that it is removably engaged between the urging means and the contact element.

In a further aspect of the invention, the urging means is adapted to provide frictional engagement of the spring probe unit with the contact element. Engagement by friction is advantageous in that it may allow for easy removal of the spring probe unit from the contact element, since no separate mechanism needs to be actuated in order to allow removal. Also, the amount of friction between the spring probe unit and the contact element can be tailored for easy removal by selecting an appropriate combination of geometry, materials and/or surface structures for the surfaces of the spring probe unit and the contact element.

In a further aspect of the invention, the urging means comprises a resilient element. Urging means comprising a resilient element may allow for simple mechanical parts to be used for the urging means, like, for example, a spring. By selecting a suitable degree of resilience of the resilient element, the urging means may be easily tailored to urge the spring probe unit against the contact element with an appropriate force for easy removal of the spring probe unit from engagement with the contact element. The degree of resilience may, for example, be tailored such that the spring probe unit can be disengaged from the contact element manually.

In a further aspect of the invention, the urging means is adapted to allow for insertion of a spring probe unit between the urging means and the contact element for removable engagement of the spring probe unit with the contact element. Insertion of a replacement spring probe unit may allow for replacing individual spring probe units without having to replace elements which comprise many spring probe units. In this way, cost and time may be saved.

In a further aspect of the invention, the urging means is adapted to allow for manual removal of a spring probe unit from removable engagement between the urging means and the contact element or for manual insertion of a spring probe unit into removable engagement between the urging means and the contact element. Manual insertion and manual removal are advantageous in that they may be performed without the help of tools or in that they may facilitate quick and cost-effective replacement of worn-out spring probe units.

The stop may provide for electrical contact between the contact element and a spring probe unit. Thus, in one aspect of the invention, the stop comprises electrically conductive material. The stop may, for example, be made from a conductive material or have an electrically conductive surface. A stop comprising electrically conductive material may provide for electrical contact between a spring probe unit, fully inserted into the contact assembly according to the current invention, and the contact element. This may improve the quality of electrical contact between spring probe unit and contact element and thereby improve the quality of a signal transmitted over the spring probe unit and the contact element.

In a further aspect of the invention, the contact element and the stop are one piece. This may make the contact element more cost-effective to manufacture and/or to assemble. The stop and the contact element may alternatively be a plurality of pieces, which are mechanically connected with each other. They may also be electrically connected with each other.

The stop provides a mechanical abutment for the spring probe unit, in a state where the spring probe unit is fully inserted into the contact assembly. The stop may have different shapes. It may, for example, comprise a flat portion in orthogonal orientation relative to the long direction of the contact element. It may alternatively comprise a curved portion, wherein the curved portion or a part of it serves as the abutment for the spring probe unit. The stop may, for example, comprise a portion having an opening, wherein the area around the opening provides the abutment. It may, for example, comprise a ring-shaped portion wherein the portion forming the ring provides the abutment. The stop may comprise one single portion providing the abutment, or of two or more separate portions providing the abutment.

The stop may be resilient. A resilient stop may still provide a mechanical abutment for the spring probe unit, in a state where the spring probe unit is fully inserted into the contact assembly. A resilient stop may still allow for precise positioning of a spring probe unit in the long direction of the contact element, in a state where no force is applied to the tip of a spring probe unit, fully inserted into the contact assembly, in its long direction. When external force is applied to the tip of the spring probe unit, the force may be absorbed by the spring in the interior of the body of the spring probe unit and by a resilient stop simultaneously. A resilient stop may make the use of a spring inside the body of a spring probe unit obsolete.

In a further aspect of the invention, the contact element further comprises a positioning feature for positioning the contact element in the contact assembly. The positioning feature may allow for a quick and cost-effective mounting of the contact element in the contact assembly, while maintaining mechanical precision of the final position of the contact element in the contact assembly.

In a further aspect of the invention, the contact element has, in at least one position along its long direction, a U-shaped or an O-shaped or a V-shaped profile in a cross section, taken in a plane perpendicular to the axis along the length of the contact element. Such profiles may be advantageous in two ways: Firstly, they may contribute to the guiding of a spring probe unit during insertion of the spring probe unit into the contact assembly. Secondly, they may provide a greater mechanical stability to the contact element by increasing its stiffness.

In a further aspect of the invention, the contact element and the urging means are one piece. The contact element may thereby be more cost-effective to manufacture and to assemble. The contact element may also be more stable, if the contact element and the urging means are one piece.

In a further aspect of the invention, the contact assembly comprises a housing, and the contact element comprises a shielding or grounding section, the shielding or grounding section being accessible from outside the housing. The feature of the shielding or grounding section being accessible from outside the housing may be particularly useful in semiconductor testing devices where certain spring probe units are required to be put on electrical ground. Through the externally accessible shielding or grounding section, an electrical ground of an adjacent element may be contacted, for example a ground contact on a mounting frame for a plurality of contact assemblies or on a probe block. A shielding or grounding section on a contact element according to the invention may be advantageous in cases where the contact element is electrically connected to the shielding braid of a coaxial cable. The shielding or grounding section may then electrically connect the contact element to the housing of the contact assembly, for example to a conductive shield box. This arrangement may ensure shielding of the contact assembly against undesired electromagnetic radiation from outside the housing of the contact assembly and/or confine any electromagnetic radiation generated inside the housing of the contact assembly essentially within the volume enveloped by the housing.

In a further aspect of the invention, at least a part of the shielding or grounding section extends to the outside of the housing of the contact assembly. This arrangement facilitates electrical contact of the contact element to any grounding or shielding elements outside the housing of the contact assembly.

In a further aspect of the invention, at least a part of the shielding or grounding section is resilient. This may be advantageous for contact assemblies in which mechanical tolerances may lead to gaps between the contact assembly and an external shielding or grounding contact, which the shielding section is supposed to electrically contact. A resilient shielding or grounding section may adapt itself to the size of the gap, thereby making any further compensation measures unnecessary.

In a further aspect, the invention provides a combination of a spring probe unit and a contact assembly as described above, wherein the spring probe unit is at least partially surrounded by the contact assembly, wherein the contact element electrically contacts the spring probe unit, and wherein the urging means removably engages the spring probe unit with the contact element by urging the spring probe unit against the contact element. The combination allows for removal of the spring probe unit from the contact assembly without exerting excessive force, and thereby facilitates replacement of one spring probe unit by another spring probe unit. This may make the replacement of elements obsolete which comprise many spring probe units. In this way, cost and time may be saved. In a further aspect, the invention provides a mounting assembly which comprises a contact assembly as described above and a mounting frame having one or more channels, each channel being adapted to receive a contact assembly as described above. Such a mounting assembly may allow to mount a larger number of contact assemblies comprising spring probe units, such that the spring probes units form, for example, an array of spring probe units, that can simultaneously contact a corresponding number of electrical nodes of a semiconductor device under test. This may speed up a test and may make it more cost-effective.

In a further aspect, the invention provides a combination of a spring probe unit and a mounting assembly as described above, wherein the spring probe unit is at least partially surrounded by the contact assembly, wherein the contact element electrically contacts the spring probe unit, and wherein the urging means removably engages the spring probe unit with the contact element by urging the spring probe unit against the contact element.

### BRIEF DESCRIPTION OF THE DRAWINGS

FIG. 1 is a perspective view of a spring probe unit;

FIG. 2 is a perspective view of a contact element according to the invention;

FIG. 3 is a perspective view of an alternative contact element according to the invention;

FIG. 4 is a perspective view of an interior of a contact assembly according to the invention;

FIG. 5 is a perspective view of an alternative contact assembly according to the invention with its cover; and

FIG. 6 is a perspective view of a mounting assembly for mounting contact assemblies, according to the invention.

### DETAILED DESCRIPTION

Herein below various embodiments of the present invention are described and shown in the drawings wherein like elements are provided with the same reference numbers. The accompanying drawings show, by way of illustration, specific embodiments in which the invention may be practiced. It is to be understood that other embodiments may be utilized and structural or logical changes may be made without departing from the scope of the present invention. The following detailed description therefore is not to be taken in a limiting sense, and the scope of the invention is defined by the appended claims.

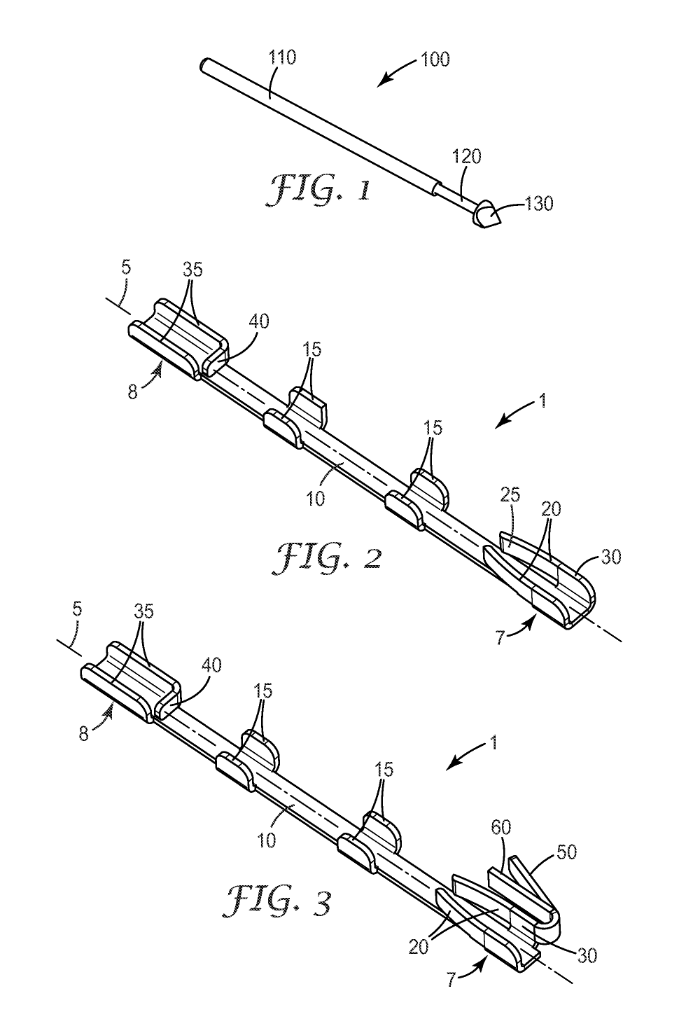

FIG. 1 shows a spring probe unit 100 in a perspective view. The spring probe unit 100 comprises a body 110 and a tip 120. The body 110 forms a hollow cylinder. The tip 120 is movable with respect to the body 110. It can be pushed into the body 110 against the force of a spring (not visible) located inside the body 110. The vertex 130 of the tip 120 is pointed. It is adapted to contact, for example, an electrical node on a semiconductor device under test. When contacting an electrical node on a semiconductor device, the spring probe unit 100 is pushed against the device, so that the spring-loaded tip 120 contacts the electrical node with some force, which force originates from the spring in the body 110 of the spring probe unit 100. In one embodiment, all parts of the spring probe unit 100 are made from highly conductive material, and they are in electrical contact with each other, so that any electrical signals can be conducted, with minimal electrical loss, through the vertex 130, the tip 120 and the spring (not shown) to the body 110 of the spring probe unit 100, from the semiconductor device under test to any test equipment used.

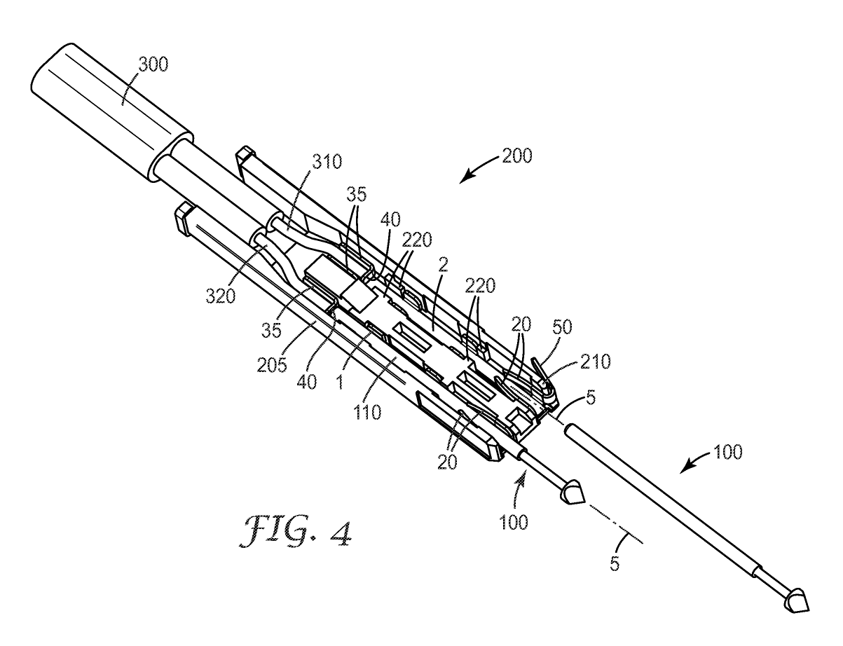

FIG. 2 is a perspective representation of a contact element 1 according to the invention. The contact element 1 is elongate, in that it has a long extension in the direction of an axis 5. It comprises a probe end portion 7 and a wire end portion 8. The contact element 1 comprises a flat base 10 and resilient positioning features 15. The positioning features 15 are arranged along opposed long edges of the base 10 and protrude into a direction perpendicular to the plane of the base 10. Two respective positioning features 15 are arranged on opposite edges of the base 10, facing each other, and forming a pair. The positioning features 15 serve to position and hold the contact element 1 in a contact assembly 200, as shown in FIG. 4.

At the probe end portion 7 of the elongate contact element 1, two resilient spring blades 20 are arranged, protruding from opposed long edges of the base 10 in a direction perpendicular to the plane of the base 10 and facing each other. Each spring blade 20 has a free end 25 and a fixed end 30. The fixed end 30 is mechanically connected to the base 10, while the free end 25 is free to move with respect to the base 10. The respective free ends 25 of the opposing spring blades 20 are curved towards each other such that the space between the free ends 25 is smaller than the space between their fixed ends 30. The spring blades 20 thereby form a guiding funnel between them, into which a body 110 of a spring probe unit 100, like the one shown in FIG. 1, may be inserted, and between which the spring probe unit 100 may be removably engaged. Since both spring blades 20 are resilient, their free ends 25 may be pushed away from each other by the body 110 of a spring probe 100 unit that is being pushed between them. The free ends 25 can removably engage the cylindrical body 110 of a spring probe unit 100 and hold it in a fixed, laterally well defined position between them, if the body 110 of the spring probe unit 100 has a larger diameter than the space formed between the free ends 25 when nothing urges the free ends 25 away from each other. The physical size of the contact element 1 and dimensions and sizes of its positioning features 15 and spring blades 20 are chosen such that the spring blades 20 can urge the body 110 of a spring probe unit 100 of a given size against the contact element 1 and provide removable engagement of the spring probe unit 100 with the contact element 1.

The contact element 1 further comprises two contacting plates 35. They are located in the vicinity of the wire end portion 8 of the contact element 1. The contacting plates 35 are arranged along the long edges of the base 10 and protrude into a direction perpendicular to the plane of the base 10. They protrude essentially in the same direction as the positioning features 15 and the spring blades 20 protrude from the base 10. The two contacting plates 35 are arranged on opposite edges of the base 10, facing each other, and forming a pair. The contacting plates 35 provide a location for electrically connecting wires (not shown) to the contact element 1, e.g. by soldering.

The contact element 1 further comprises a stop 40. When a spring probe unit 100 is removably engaged with the contact element 1, the stop 40 restrains the movement of the spring probe unit 100 towards the stop 40 in the direction of the axis 5 along the length of the contact element 1. The stop 40 protrudes from one of the contacting plates 35. The stop 40 and the contacting plate 35 from which it protrudes are one piece. The stop 40 is flat. It is bent by an angle of 90° with respect to the contacting plate 35 from which it protrudes, so that its plane is perpendicular to the axis 5 along the length of the contact element 1. The stop 40 is rigid enough to provide a solid abutment for a body 110 of a spring probe unit 100 that is removably engaged with the contact element 1, even in a state where the spring probe unit 100 is pushed against an electrical node of a semiconductor device under test, i.e. in a state in which the spring-loaded tip 120 of the spring probe unit 100 exerts force on the body 110 of the spring probe unit 100.

Each of the spring blades 20 is adapted to urge, by virtue of its resilience, a spring probe unit 100 against the contact element 1. Each spring blade 20 urges the spring probe unit 100 against the other, opposing spring blade 20. By urging the spring probe unit 100 against the contact element 1, it provides removable engagement of the spring probe unit 100 with the contact element 1. In the embodiment shown here, the engagement is removable, because the spring probe unit 100 is held in place by friction between the outer surface of the body 110 of the spring probe unit 100 and the spring blades 20. The spring constant of the spring blade 20 is chosen such that the spring probe unit 100 can be pulled out from between the spring blades 20 without exerting strong forces. Each spring blade 20 thus provides a frictional engagement of the spring probe unit 100 with the contact element 1.

In the embodiment shown here, the spring blades 20 are adapted to act as electrical contacts between the contact element 1 and the body 110 of a spring probe unit 100 pushed between them. An electrical signal, picked up from an electrical node of a semiconductor device under test, is thus conducted through the spring probe unit 100 and the spring blades 20 to the base 10 and further to the contacting plates 35 of the contact element 1, where a wire of a cable may be connected, as shown, for example, in FIG. 4. The electrical signal is also conducted through the spring probe unit 100 and the stop 40 to the contacting plates 35.

Where the opposing positioning features 15 are located along the length of the contact element 1, the base 10 of the contact element 1 forms, in conjunction with the opposing positioning features 15, a U-shaped profile in a cross section, taken in a plane perpendicular to the axis 5 along the length of the contact element 1.

In one embodiment, the contact element 1 shown in FIG. 2 is made out of one piece of conductive metal. Hence the contact element 1, the positioning features 15, the contacting plates 35, the stop 40, and the spring blades 20 are one piece.

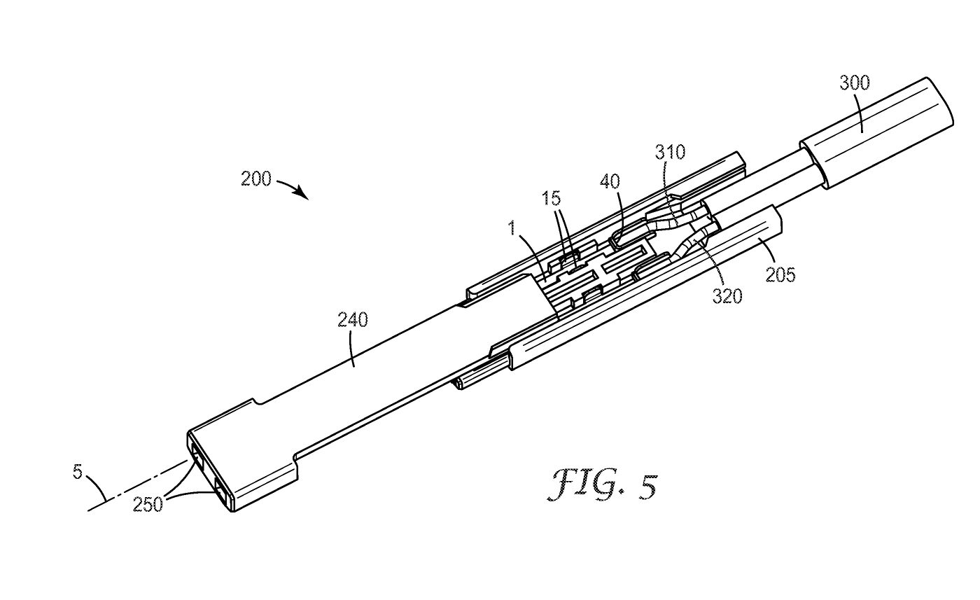

FIG. 3 shows, in a perspective view, an alternative contact element 2, which is identical to the contact element 1 of FIG. 2, except for an additional grounding or shielding section 50, and a fixing clip 60. Both the grounding or shielding section 50 and the fixing clip 60 protrude from the fixed end 30 of one of the spring blades 20. The grounding or shielding section 50 is resilient and electrically conductive. It extends from the spring blade 20 in a direction almost parallel to the spring blade 20, but at a flat angle with respect to the plane of the spring blade 20, and extends generally towards the wire end portion 8. When mounted in a contact assembly 200 like the one shown in FIG. 4, the grounding or shielding section 50 extends to the outside of a housing (for example, one as shown in FIG. 5) of the contact assembly 200 in such a way that it can electrically and mechanically contact an adjacent surface, for example a surface that is oriented parallel to the plane of the fixed end 30 of the spring blade 20. The grounding or shielding section 50 may, for example, contact a so-called shield box (not shown), i.e. a conductive housing of a contact assembly 200 comprising a contact element 2.

The fixing clip 60 is resilient, too. It forms, in conjunction with the spring blade 20 from which it protrudes, a U-shape, the open side of the U being oriented towards the wire end portion 8 of the contact element 1. The inner size of the “U” is chosen large enough to bend around an edge of the base 205 of the housing of the contact assembly 200 shown in FIG. 4, so that the fixing clip 60 is located outside the housing. The resilient fixing clip 60 clips onto an edge of the base 205 and serves to fix the contact element 2 relative to the base 205 of the housing of a contact assembly 200, so that a force exerted on the grounding or shielding section 50 is absorbed by the fixing clip 60 and is not absorbed by deformation of parts of the spring blades 20 located inside the base 205 of the housing.

In the embodiment shown here, the grounding or shielding section 50 is used to electrically connect the contact element 2 with an external contact surface that is on ground potential. Thereby, a spring probe unit 100 that might be engaged with the contact element 2, can be put on electrical ground. However, the same grounding or shielding section 50 may alternatively be used to connect the contact element 2 with an external contact surface that is on a different electrical potential. Thereby, a spring probe unit 100 that might be engaged with the contact element 2, can be put on that electrical potential. Putting the contact element 2 or a spring probe unit 100 that might be engaged with the contact element 2 on a specific electrical potential may help in shielding parts of a semiconductor device test equipment, which comprises the contact element 2, against undesired electromagnetic radiation from adjacent contact assemblies 200 or from other sources. The grounding or shielding section 50 may thus alternatively be used for electrical shielding.

FIG. 4 is a perspective view of a contact assembly 200 according to the present invention. The contact assembly 200 comprises a housing comprising a base 205 and a cover 240 (not shown), and two contact elements 1, 2. In FIG. 4, the cover 240 (shown in FIG. 5) has been removed in order to reveal the inside of the contact assembly 200. The base 205 is made from electrically insulating material. A twinaxial cable 300, comprising two conductors 310, 320, is electrically connected to the contact assembly 200. In embodiment shown in FIG. 4, the cable 300 is electrically connected by soldering or any other suitable method, specifically the first conductor 310 of the cable 300 is electrically connected to the contacting plates 35 of the one contact element 2, and the second conductor 320 is electrically connected to the contacting plates 35 of the other contact element 1 at the respective wire end portions 8 of the contact elements 1, 2. The contact element 2 comprises a grounding or shielding section 50 and a fixing clip 60 protruding from one of the spring blades 20 which is located adjacent to the edge 210 of the base 205. The fixing clip 60 is not visible in FIG. 4. The contact element 2 is not engaged with a spring probe unit 100.

A first spring probe unit 100 is shown outside the contact assembly 200, in an orientation ready for insertion into the contact assembly 200 towards the stop 40 in the direction of the axis 5 along the length of the contact element 2.

A second spring probe unit 100 is shown fully engaged with the other contact element 1. It is fully inserted into the contact assembly 200 in the direction of the axis 5 along the length of the contact element 1, towards the stop 40. It is fully inserted, such that its body 110 abuts the stop 40 of the contact element 1. The two spring blades 20 of the contact element 1 urge the second spring probe unit 100 against the contact element 1 and thereby provide a removable engagement of the spring probe unit 100 with the contact element 1. The contact element 1 electrically contacts the spring probe unit 100 through the stop 40 and the free ends 25 of the spring blades 20. The spring blades 20 provide removable engagement, specifically a frictional engagement, of the spring probe unit 100 with the contact element 1, so that the spring probe unit 100 is secured in the contact assembly 200. However, the engagement is removable in that the spring blades 20 engage the spring probe unit 100 such that the spring probe unit 100 can be pulled out of the contact assembly 200 without having to exert strong force. Specifically, the spring probe unit 100 can be pulled out of the contact assembly 200 manually by pulling on the part of the body 110 of the spring probe unit 100 that is accessible from outside the base 205 of the contact assembly 200 in the direction of the axis 5 along the length of the contact element 1.

The contact elements 1, 2 are positioned and held in the base 205 by engagement of resilient positioning features 15 with corresponding protrusions 220 on inner surfaces of the base 205. Due to the resilience of the positioning features 15, the contact elements 1, 2 can be pressed, for example during assembly of a contact assembly 200, into a tight, resilient fit with inner surfaces of the base 205 and with the protrusions 220, and position and hold the contact elements 1, 2 in a fixed position also in directions perpendicular to the long direction of the respective contact elements 1, 2.

In place of the twinaxial cable 300, a coaxial cable might alternatively be connected to the contact assembly 200. Coaxial cables typically comprise a central signal conductor and a coaxial shielding braid. The signal conductor of the coaxial cable may then be connected to the contact element 1, and the shielding braid of the coaxial cable may be connected to the contact element 2, which comprises the grounding/shielding section 50.

FIG. 5 is a perspective view of a contact assembly 200 similar to the one of FIG. 4, but not having a contact element 2 comprising a grounding or shielding section 50. A cover 240 and a base 205 form a housing of the contact assembly 200. The cover 240 is partly covering the base 205. The cover 240 and the base 205 are configured such that the cover 240 can be slidingly engaged with the base 205 by pushing it in the direction of an axis 5 along the length of a contact element 1 into a position where it completely covers the base 205. In this position, the contact assembly 200 is closed. Additional locking or latching features (not shown) may be provided on the base 205 or on the cover 240 or on both, to prevent accidental opening of the contact assembly 200. Both the base 205 and the cover 240 are made from electrically insulating material. The cover 240 has two openings 250 through which spring probe units 100 can be inserted into the contact assembly 200 for removable engagement with the contact elements 1, 2.

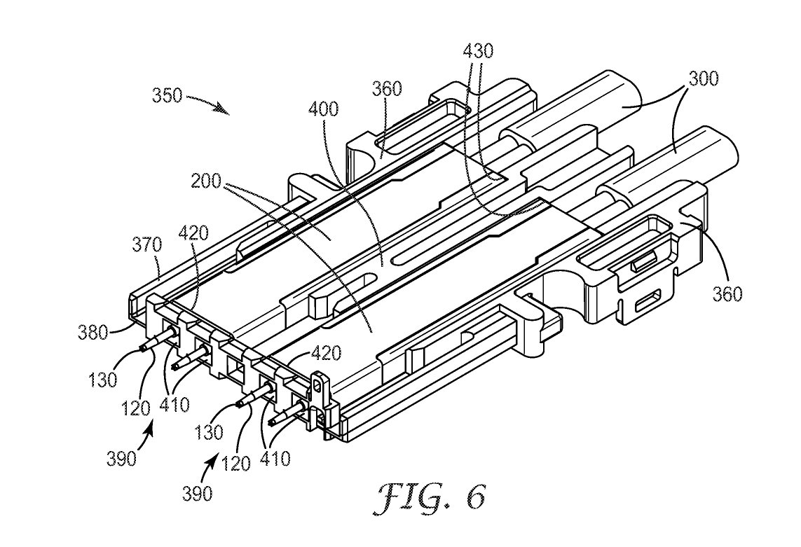

A plurality of contact assemblies 200 may be arranged to form a mounting assembly 350, as shown in FIG. 6, which provides support for number of spring probe units 100. Such a mounting assembly 350 may allow mounting of contact assemblies 200, such that the tips 120 of spring probe units 100, inserted into the contact assemblies 200, can simultaneously contact electrical nodes of a semiconductor device under test. Thereby, the mounting assembly 350 performs a function of a probe block of a piece of test equipment mentioned earlier.

FIG. 6 is a perspective view of an embodiment of such a mounting assembly 350. The mounting assembly 350 comprises two contact assemblies 200 and a mounting frame 360. The mounting assembly 350 includes an upper surface 370 and an opposing lower surface 380. The upper surface 370 and the lower surface 380 are defined by a front edge, a back edge and two longitudinal side edges. The upper surface 370 of the mounting frame 360 has two longitudinal channels 390 separated by a rib 400. The channels 390 extend from openings 410 in the front edge towards the back edge of the mounting frame 360. Each channel 390 is adapted to receive a contact assembly 200 and retain it securely within the mounting frame 360. Once a contact assembly 200 is fully inserted into a channel 390, the end of the contact assembly 200, which is located next to the spring blades 220 of the contact element 1 mounted in it, abuts an interior surface 420 of the front edge of the mounting frame 360. The openings 410 in the front edge are configured to allow insertion of a corresponding number of individual spring probe units 100 into the contact assemblies 200 positioned within the channels 390 of the mounting frame 360. The openings 410 also allow removal of individual spring probe units 100 from the contact assemblies 200. The Figure shows four spring probe units 100 fully inserted into the two contact assemblies 200, so that only their respective tips 120 are visible. The vertices 130 of the spring probe units 100 in the embodiment shown in this Figure are shaped differently from the vertices 130 of the spring probe unit 100 shown in FIGS. 1 and 4.

Each channel 390 includes abutments 430, which are configured to assist in retaining the contact assembly 200 in the mounting frame 360. The contact assemblies 200 may be retained within the mounting frame 360 by any suitable method, such as, for example, snap fit, friction fit, press fit, or mechanical clamping. Generally, a plurality of contact assemblies 200 may be mounted in a mounting frame 360 to form a probe block. Generally, a plurality of mounting frames 360, each holding a plurality of contact assemblies 200, may be fixed to each other in any suitable way and in any suitable geometric arrangement to form a probe block.

What is claimed is:

1. A contact assembly for receiving a spring probe unit,
comprising an elongate contact element adapted to electrically contact the spring probe unit,
the contact element comprising
a stop for restraining movement of the spring probe unit towards the stop in the direction of an axis along the length of the contact element,
and
urging means adapted to urge the spring probe unit against the contact element for removable engagement of the spring probe unit with the contact element.

2. The contact assembly according to claim 1, wherein the urging means is adapted to provide frictional engagement of the spring probe unit with the contact element.

3. The contact assembly according to claim 1, wherein the urging means comprises a resilient element.

4. The contact assembly according to claim 1, wherein the urging means is adapted to allow for insertion of a spring probe unit between the urging means and the contact element for removable engagement of the spring probe unit with the contact element.

5. The contact assembly according to claim 1, wherein the urging means is adapted to allow for manual removal of a spring probe unit from removable engagement between the urging means and the contact element or for manual insertion of a spring probe unit into removable engagement between the urging means and the contact element.

6. The contact assembly according to claim 1, wherein the contact element and the stop are one piece.

7. The contact assembly according to claim 1, wherein the stop comprises electrically conductive material.

8. The contact assembly according to claim 1, wherein the contact element further comprises a positioning feature for positioning the contact element in the contact assembly.

9. The contact assembly according to claim 1, wherein the contact element has, in at least one position along its long direction, a U-shaped or an O-shaped or a V-shaped profile in a cross section, taken in a plane perpendicular to the axis along the length of the contact element.

10. The contact assembly according to claim 1, wherein the contact element and the urging means are one piece.

11. The contact assembly according to claim 1, wherein the contact assembly comprises a housing, and wherein the contact element comprises a shielding or ground section, the shielding or grounding section being accessible from outside the housing.

12. The contact assembly according to claim 11, wherein at least a part of the shielding or grounding section extends to the outside of the housing.

13. The contact assembly according to claim 11, wherein at least a part of the shielding or grounding section is resilient.

14. A combination of a spring probe unit and a contact assembly according to claim 1,
wherein the spring probe unit is at least partially surrounded by the contact assembly,
wherein the contact element electrically contacts the spring probe unit, and
wherein the urging means removably engages the spring probe unit with the contact element by urging the spring probe unit against the contact element.

15. A mounting assembly, comprising
a contact assembly according to claim 1, and
a mounting frame having one or more channels, each channel being adapted to receive a contact assembly according to claim 1.

16. A combination of a spring probe unit and a mounting assembly according to claim 15, wherein the spring probe unit as at least partially surrounded by the contact assembly,
wherein the contact element electrically contacts the spring probe unit, and
wherein the urging means removably engages the spring probe unit with the contact element by urging the spring probe unit against the contact element.
